(19) United States
(12) Patent Application Publication
(10) Pub. No.: US 2004/0263219 A1
(43) Pub. Date: Dec. 30, 2004

(54) Drive circuit and drive method

(76) Inventor: Kiminori Ozaki, Kariya-shi (JP)

Correspondence Address: MORGAN & FINNEGAN, L.L.P., 3 WORLD FINANCIAL CENTER, NEW YORK, NY, 10281-2101, US

(21) Appl. No.: 10/873,776

(22) Filed: Jun. 22, 2004

(30) Foreign Application Priority Data
Jun. 30, 2003 (JP) 2003-186424

(51) Int. Cl. H03B 1/00

(52) U.S. Cl. 327/112

(57) ABSTRACT

A drive circuit for a switching device includes a condenser and a leakage route. The switching device includes a standard terminal and a control terminal, and conduction of switching device is controlled in response to voltage that is applied to the control terminal with respect to the standard terminal. The condenser has a first end and a second end. A switching control signal is inputted to the first end, and the second end is connected to the control terminal. The leakage route connects the standard terminal and the control terminal.

### BACKGROUND OF THE INVENTION

The present invention relates to a drive circuit that controls the switching of a voltage control device such as a MOS transistor and an insulated gate bipolar transistor (IGBT) device, more particularly to a drive circuit that steadily maintains the non-conduction state of a switching device.

Conventionally, a voltage control device such as a MOS transistor and an IGBT device is used as a switching device for electric power control such as motor control. In bridge drivers, a switching device in an upper arm and a switching device in a lower arm are exclusively controlled to conduct so that electric power control is performed. Due to recent development in electric power control technique, required switching speed of these switching devices tends to be higher. Upon high speed switching, the control voltage of the device at an off state can transiently fluctuate, due to the device and a parasitic device that exists in a connecting wire, such that the device may unintentionally ignite, that is, may unintentionally turn into an on state. Thus, unnecessary electric current such as penetration electric current flows in the device. To prevent the above unintentional ignition, a circuit technique is proposed that the control voltage level at the off state is compulsorily reverse biased.

For example, in a motor control device disclosed in Japanese Unexamined Patent Publication No. 2000-341970 as shown in FIGS. 12 and 13, an output winding from a power source transformer TR100 is connected to diodes D200, D300 and condensers C300, C400 to form positive and negative power sources for a switching device QM200 in a lower arm. Positive and negative bias power sources are supplied to the switching device QM200 for on-off control.

In a switching device QM100 in an upper arm, a condenser C100 is charged from the condenser C300 via a diode D100, and positive bias power source is supplied to the switching device QM100 for on control. Furthermore, a condenser C500 is connected to an integrated circuit IC100 in a switched capacitor circuit 700 and is charged. The integrated circuit IC100 switches from “a” to “b” at predetermined intervals to charge a condenser C200. The condenser C100 is reversely connected to the condenser C200 via the switched capacitor 700. Thus, the condenser C200 is charged with negative voltage by repeatedly switching the integrated circuit IC100, while negative bias power source is supplied to the switching device QM100 for off control.

However, in the above reference, it is necessary to provide the positive and negative power sources by using the power source transformer TR100 for controlling the conduction of the switching device QM200 in the lower arm. Namely, the diodes D200 and D300 that rectify the voltage output from the power source transformer TR100 and the condensers C300 and C400 that smooth the rectified voltage output are required in each of the positive and negative power sources. Thus, the drive circuit is large-sized.

Instead of a dedicated power source transformer, the switched capacitor circuit 700 needs to be provided for controlling the conduction of the switching device QM100 in the upper arm. In the switched capacitor circuit 700, electrical charge in the condenser C100 is moved to the condenser C200 by repeatedly switching the control circuit IC100. Thereby, the negative voltage is generated in the condenser C200. To generate the negative voltage in the condenser C200, the switching that is required for generating the negative voltage in the switched capacitor circuit 700 is generally required at frequency that is different from operation frequency required for electric power control by a bridge driver. Control signals, such as dedicated clock signals (not shown), need to be supplied or generated. Thus, a dedicated circuit and dedicated control signals are required for generating the negative voltage.

### SUMMARY OF THE INVENTION

The present invention provides a drive circuit that supplies control voltage signals of positive and negative voltages that are required for controlling the conduction of a switching device, in synchronization with transition of switching signals, without an additional circuit such as a control circuit that operates with dedicated control timing.

According to the present invention, a drive circuit for a switching device includes a condenser and a leakage route. The switching device includes a standard terminal and a control terminal, and conduction of switching device is controlled in response to voltage that is applied to the control terminal with respect to the standard terminal. The condenser has a first end and a second end. A switching control signal is inputted to the first end, and the second end is connected to the control terminal. The leakage route connects the standard terminal and the control terminal.

The present invention also provides a drive method for a switching device that includes a standard terminal and a control terminal. Conduction of the switching device is controlled in response to voltage that is applied to the control terminal with respect to the standard terminal. The drive method comprising the steps of; propagating transition of voltage level of a switching control signal to the control terminal by capacitive coupling so as to set an initial value of the voltage; and reducing the voltage after the propagating step.

### BRIEF DESCRIPTION OF THE DRAWINGS

The features of the present invention that are believed to be novel are set forth with particularity in the appended claims. The invention together with objects and advantages thereof, may best be understood by reference to the following description of the presently preferred embodiments together with the accompanying drawings in which:

FIG. 1 is a circuit diagram of a drive circuit when used for a bridge driver according to the present invention;

FIG. 2 is a circuit diagram of a drive circuit according to a first preferred embodiment;

FIG. 3 is a wave form chart showing the action of the drive circuit according to the first preferred embodiment;

FIG. 4 is a circuit diagram of a drive circuit according to a second preferred embodiment;

FIG. 5 is a wave form chart showing the action of the drive circuit according to the second preferred embodiment;

FIG. 6A is a diagram of a voltage clamp portion in a drive circuit according to a third preferred embodiment;

FIG. 6B is a diagram of a voltage clamp portion in a drive circuit according to a fourth preferred embodiment;

FIG. 7 is a circuit diagram of a drive circuit according to a fifth preferred embodiment;

FIG. 8A is a diagram of a voltage clamp portion of a drive circuit according to a sixth preferred embodiment;

FIG. 8B is a diagram of a voltage clamp portion of a drive circuit according to a seventh preferred embodiment;

FIG. 8C is a diagram of a voltage clamp portion of a drive circuit according to an eighth preferred embodiment;

FIG. 9 is a circuit diagram of a drive circuit according to a first alternative embodiment;

FIG. 10 is a circuit diagram of a drive circuit according to a second alternative embodiment;

FIG. 11 is a circuit diagram of a drive circuit according to a third alternative embodiment;

FIG. 12 is a circuit diagram of a drive circuit according to prior art; and

FIG. 13 is a circuit diagram of a switched capacitor circuit in the drive circuit according to the prior art.

### DETAILED DESCRIPTION OF THE PREFERRED EMBODIMENTS

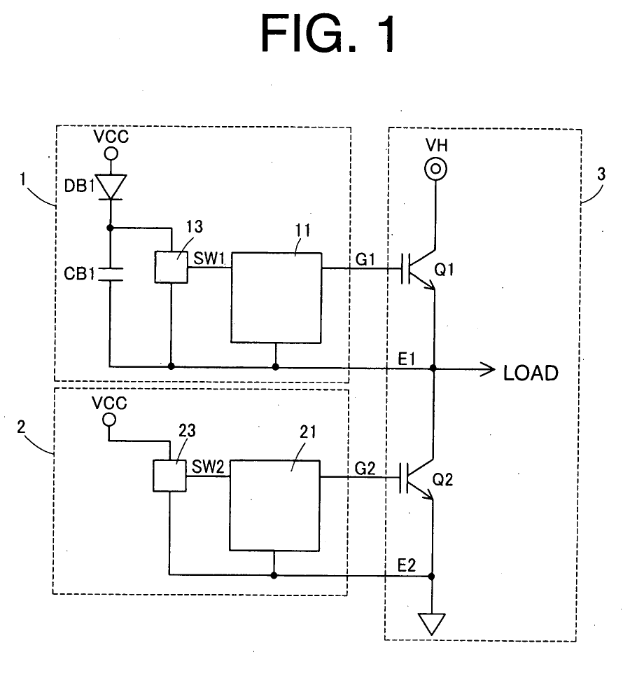

Hereinafter, preferred embodiments according to the present invention will be described with reference to FIGS. 1 through 8C. The present invention is applied to a drive circuit and a drive method in the preferred embodiments. An insulated gate bipolar transistor (IGBT) device is utilized as a switching device in the preferred embodiments.

As shown in FIG. 1, an IGBT device Q1 in an upper arm and an IGBT device Q2 in a lower arm are serially connected to a bridge driver 3 between a high voltage power source VH and a standard power source. In drive circuits 1 and 2 that control the conduction of the bridge driver 3, switching control signals are outputted to output wires SW1 and SW2 after conduction timings for the IGBT devices Q1 and Q2 are controlled by switching controllers 13 and 23. Level converting parts 11 and 21, according to the present invention, are respectively provided between the output wires SW1 and a gate terminal G1, as a control terminal of the IGBT device Q1, and between the output wire SW2 and a gate terminal G2, as a control terminal of the IGBT device Q2, for converting levels of the voltages that are applied to the gate terminals G1 and G2. The level converting parts 11 and 21 respectively generate gate voltages that are voltages of the gate terminals G1 and G2 with respect to emitter terminals E1 and E2, as standard terminals of the IGBT devices Q1 and Q2.

Apart from the emitter terminals E1 and E2, only the switching control signals are input to the level converting parts 11 and 21, and dedicated power sources are unnecessary in the level converting parts 11 and 21 for supplying level-converted gate voltage to the gate terminals G1 and G2. Also, a voltage, whose level is consistently converted into the positive or negative side in response to the voltage transition of the inputted switching control signal, is outputted from the level converting parts 11 and 21 to the gate terminals G1 and G2.

Since it is necessary to ensure electric power in the bridge driver 3 for electric power drive, the high voltage power source VH is required to apply relatively high voltage, for example, a voltage of about 300V. On the other hand, power sources VCC for the drive circuit 1 and 2 are power sources for electric power control, and are relatively low voltage, for example, several tens of volts. Different power sources are generally and respectively supplied to the drive circuits 1 and 2 and the bridge driver 3.

The voltage of the emitter terminal E1 rises to the voltage of the high voltage power source VH upon the conduction of the IGBT device Q1, and the standard voltage of the switching controller 13, that is connected thereto, also rises. Thus, the voltage of the power source supplied by the power source VCC to the switching controller 13 in the upper arm is boosted by a diode DB1 and a condenser CB1.

Still referring to FIG. 1, the drive circuits 1 and 2 have the same circuit structure except for the components for boosting the power source supplied to the switching device 13 by the condenser CB1 upon the conduction of the IGBT device Q1. Thus, only the drive circuit 1 is described hereinafter.

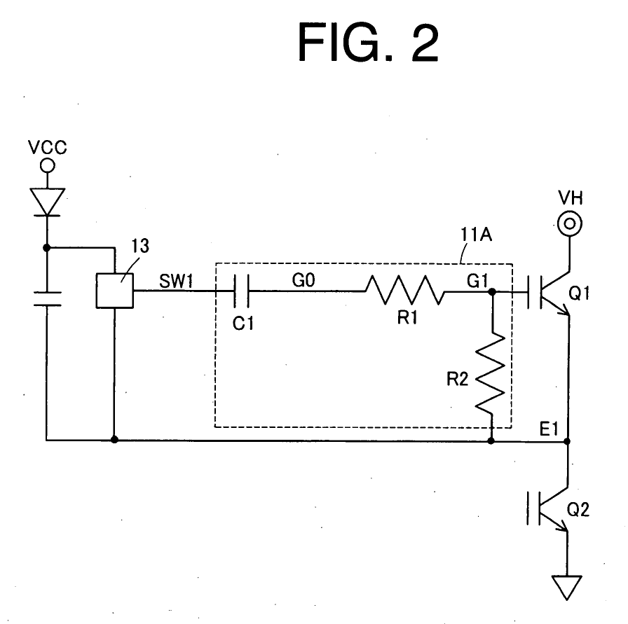

As shown in FIG. 2, the drive circuit 1 has a level converting part 11A according to a first preferred embodiment. The output wire SW1 from the switching controller 13 is connected to one terminal of a condenser C1, and the other terminal G0 of the condenser C1 is connected to the gate terminal G1 of the IGBT device G1 via a resistance device R1 for limiting current. A resistance device R2 is also connected between the gate terminal G1 and the emitter terminal E1.

When the voltage level of a switching control signal V (SW) that is outputted to the output wire SW1 transits, an amount of the voltage transition in response to an amount of the voltage transition of the switching control signal V (SW) is induced at the terminal G0 that is capacitive-coupled via the condenser C1 in addition to the voltage level before capacitive coupling. The voltage induced at the terminal G0 is level-converted through the resistance device R1 and is applied to the gate terminal G1.

The voltages at the terminal G0 and the gate terminal G1 are induced by accumulating electric charge in capacitive elements at the terminal G0 and between the gate terminal G1 and the emitter terminal E1 due to the IGBT device Q1 and other parasitic elements. Thus, the resistance device R2 functions as a leakage route for accumulated electric charge, and the electric charge in the capacity elements that maintain the induced voltage is discharged. Therefore, as time elapses, the applied voltage induced at the terminal G0 and the gate terminal G1 is decreased. The resistance device R1 is a current limiting resistance for limiting rush current when the electric charge that is supplied to the terminal G0 in response to the voltage transition of the switching control signal V (SW) reaches the gate terminal G1.

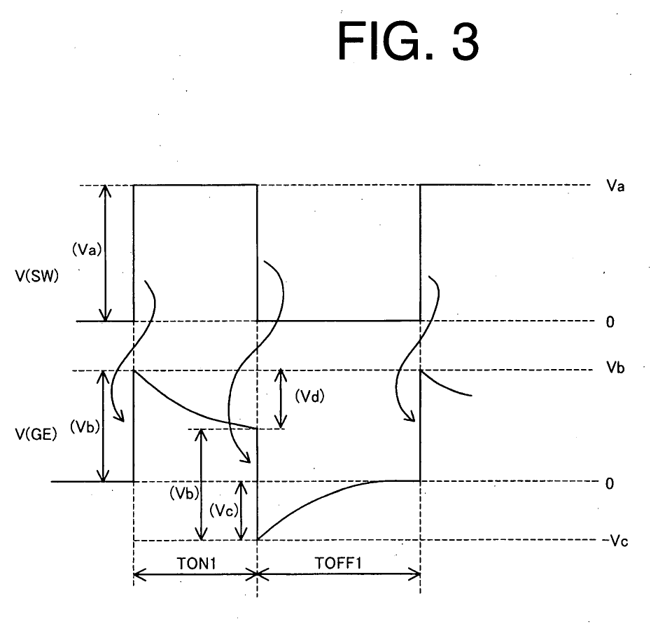

A state during the voltage transition of the switching control signal V (SW) will be described according to the wave form chart in FIG. 3. The switching control signal V (SW) is a two-value signal for controlling the conduction of the IGBT device Q1. When the switching control signal V (SW) is at a low voltage level before the voltage level of the switching control signal V (SW) transits, the voltage of the terminal GO and the voltage of the gate terminal G1 and the emitter terminal E1 are maintained at the same level due to the resistance device R2, and a gate voltage V (GE) is at 0 V. Hereinafter, it is assumed that a small amount of electric current flows in the resistance devices R1 and R2, while the potential difference between the terminals of the resistance device R1 or R2 is small, and the voltages of the terminal G0 and the gate terminal G1 are substantially the same.

When the switching control signal V (SW) transits from the low voltage level to a high voltage level according to command (not shown) for the conduction of the IGBT device Q1, the positive gate voltage V (GE) is induced at the gate terminal G1 with respect to the emitter terminal E1, due to the capacitive coupling via the condenser C1. At this time, the gate voltage V (GE) is at a voltage value Vb in response to an amount of the voltage transition (Va) of the switching control signal V (SW). The capacity element existing at the output wire SW1 is only the condenser C1. In an ideal state that the voltage transition of the switching control signal V (SW) is capacitive-coupled to only the condenser C1, the voltage that is equal to the amount of the voltage transition (Va) of the switching control signal V (SW) is induced as the gate voltage V (GE) (Vb=Va). In fact, since there is other capacity element at the output wire SW1 apart from the condenser C1, an amount of the voltage capacitive-coupled to the condenser C1 corresponds to a part of the amount of the voltage transition (Va), and Vb is generally smaller than Va.

After the voltage transition, the gate voltage V (GE) (=Vb) that is induced at the gate terminal G1 is discharged via the resistance device R2 as the leakage route during a conduction period TON1 until the switching control signal V (SW) turns over or transits from the high voltage level to the low voltage level. The above electric discharge is performed by the capacity elements existing at the terminal G0 and between the gate terminal G1 and the emitter terminal E1 due to the IGBT device Q1 and the other parasitic devices and by a CR time constant circuit including the resistance device R2 or the resistance devices R1 and R2. The voltage value is decreased at CR timing constant.

On the other hand, when the switching control device V (SW) transits from the high voltage level to the low voltage level according to command (not shown) for non-conduction of the IGBT device Q1, the gate voltage V (GE) at the gate terminal G1 is level shifted to the negative side by the voltage value (Vb) due to the capacitive coupling via the condenser C1. Before the level shift, the gate voltage V (GE) is reduced from the initial voltage value Vb at the beginning of the conduction period TON1 by a voltage value Vd due to the leakage route. Since the reduced gate voltage V (GE) is level shifted to the negative side by the voltage value Vb, the gate voltage V (GE) reaches a negative voltage value −Vc after the switching control signal V (SW) transits from the high voltage level to the low voltage level.

The amount of the level shift (−Vb) induced at the gate terminal G1, in response to the amount of the voltage transition (−Va) of the switching control signal V (SW), is smaller than the amount of the voltage transition (−Va) as described above. Leaking current is adjusted by choosing resistance values of the resistance devices R1 and R2 based on the amount of the level shift (−Vb) with respect to the amount of the voltage transition (−Va) and the length of the conduction period TON1, thereby, the voltage drop (Vd) of the gate terminal V (GE) is determined. Consequently, the gate voltage V (GE) reaches the negative voltage value when the switching control signal V (SW) transits from the high voltage level to the low voltage level.

After the gate voltage V (GE) is biased to the largest negative voltage as an initial voltage value −Vc at the beginning of a non-conduction period TOFF1, in which the switching control signal V (SW) is maintained at the low voltage level, the magnitude of negative voltage is reduced as time elapses, similar to during the conduction period TON1. The gate voltage V (GE) is biased to the largest negative voltage immediately after the switching control signal V (SW) transits to the low voltage level. Thus, even when transient voltage fluctuation occurs upon the transition of the switching control signal V (SW), the gate voltage V (GE) is effectively prevented from being a positive voltage that is equal to or larger than a threshold voltage, thereby effectively preventing the IGBT device Q1 from transiently and unintentionally igniting immediately after the IGBT device Q1 is shifted to the non-conduction state.

During the non-conduction period TOFF1, the gate voltage V (GE) is reduced as time elapses due to the resistance devices R1 and R2 and finally reaches 0V. However, the transient voltage fluctuation does not occur at a stationary state. Thus, the gate voltage V (GE) is maintained at the negative voltage value during a transient period in transition state, and the unintentional ignition of the IGBT device Q1 is effectively prevented.

If the gate voltage V (GE) has returned to 0V at the end of the non-conduction period, the amount of the level shift (Vb) by the capacitive coupling is applied as the gate voltage V (GE) when the switching control signal V (SW) transits from the low voltage level to the high voltage level according to the subsequent command (not shown) for the conduction of the IGBT device Q1. Thus, the gate voltage V (GE) is kept at a constant value at the beginning of the conduction of the IGBT device Q1, and conduction state of the IGBT device Q1 is also kept constant at the beginning of the conduction of the IGBT device Q1.

According to the drive circuit in the first preferred embodiment, as described in detail above, when the switching control signal V (SW) as the two-value signal reversely transits to switch between the conduction period TON1 and the non-conduction period TOFF1 of the IGBT device Q1, a remaining gate voltage V (GE) is smaller than the initial voltage at the voltage transition of the switching control signal V (SW), due to the electric discharge by the leakage route or the resistance devices R1 and R2. Thus, the gate voltage V (GE) swings to the reversed polarity relative to the electric potential of the emitter terminal E1, due to the voltage transition of the switching control signal V (SW). Upon shifting from the conduction period TON1 to the non-conduction period TOFF1, the remaining gate voltage V (GE) is at a voltage value of “Vb-Vd”. The remaining gate voltage V (GE) is level shifted to the negative side by the voltage value Vb and is biased to the voltage value −Vc as the initial voltage to start the non-conduction period TOFF1. On the other hand, upon shifting from the non-conduction period TOFF1 to the conduction period TON1, the gate voltage V (GE) is at 0V. Also, the gate voltage V (GE) is level shifted from 0V to the positive side by the voltage value Vb and is forward biased to a voltage value of Vb as the initial voltage to start the conduction period TON1.

Since the gate voltage V (GE) is reverse biased to the negative voltage at the beginning of the non-conduction period TOFF1, the gate voltage V (GE) is effectively prevented from being biased to the positive voltage over the threshold voltage of the IGBT device Q1, thereby preventing the IGBT device Q1 that is shifted to the non-conduction state from unintentionally igniting. The resistance values of the resistance devices R1 and R2 are adjusted according to the amplitude of the switching control signal V (SW), the conduction period TON1 of the IGBT device Q1 and the capacitance value of the capacity element connected to the gate terminal G1, so as to determine the voltage drop value Vd of the gate voltage V (GE) at the end of the conduction period TON1. Thereby, the negative voltage that absorbs voltage fluctuation causing the unintentional ignition is adjusted.

Furthermore, when the gate voltage V (GE) is set at 0V upon shifting to the conduction period TON1 due to the decrease in the gate voltage V (GE) during the non-conduction period TOFF1, the gate voltage V (GE) is level shifted to the voltage value Vb, due to shifting the IGBT device Q1 to the conduction state. The gate voltage V (GE) is maintained at the predetermined voltage value Vb at the beginning of the conduction period TON1, and conduction characteristics of the IGBT device are kept constant.

In this case, the gate voltage V (GE) reaches 0V in the final stage or the second half of the non-conduction period TOFF1 due to the decrease in the gate voltage V (GE) during the non-conduction period TOFF1. However, at the time, a transient period of the voltage transition of the switching control signal V (SW) has completed and the switching control signal V (SW) has been shifted to the stationary state. Thus, the gate voltage V (GE) does not transiently fluctuate, so that the IGBT device is effectively maintained at the non-conduction state even though the gate voltage V (GE) is at 0V.

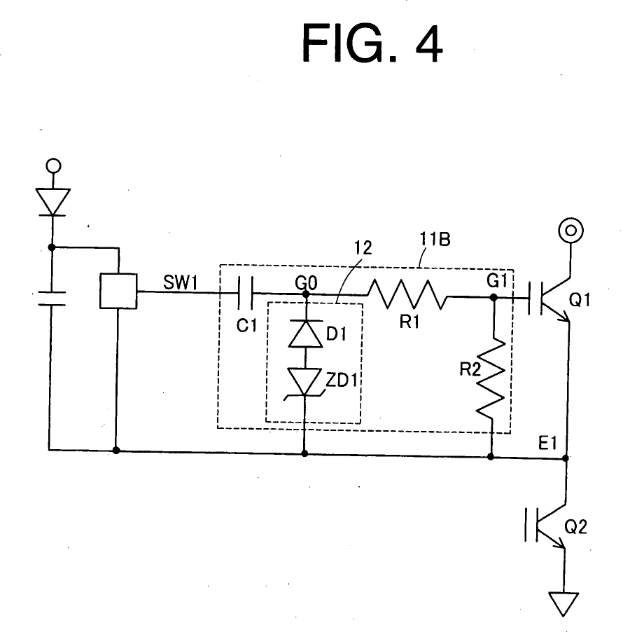

As shown in FIG. 4, a drive circuit according to a second preferred embodiment includes a level converting part 11B instead of the level converting part 11A according to the first preferred embodiment as shown in FIG. 2. The level converting part 11B is formed such that a voltage clamp portion 12 that clamps the gate voltage V (GE) to a negative voltage value upon the non-conduction is additionally provided to the level converting part 11A. The voltage clamp portion 12 includes a diode device D1 and a Zener diode device ZD1. The cathode terminal of the diode device D1 is connected to the terminal G0, and the cathode terminal of the Zener diode ZD1 is connected to the emitter terminal E1. The anode terminal of the diode device D1 is connected to that of the Zener diode ZD1.

Thus, when the switching control signal V (SW) transits from the low voltage level to the high voltage level and the positive voltage is induced at the terminal G0 upon the conduction of the IGBT device Q1, the diode device D1 is reverse biased so that the voltage clamp portion 12 is maintained at the non-conduction state. On the other hand, when the switching control signal V (SW) transits from the high voltage level to the low voltage level and the negative voltage is induced at the terminal G0 upon the conduction of the IGBT device Q1, the diode device D1 is forward biased. Therefore, a constant Zener voltage is generated at the Zener diode device ZD1, and the gate voltage V (GE) is clamped to the negative voltage of a sum of the Zener voltage and a substantially constant forward voltage of the diode device D1.

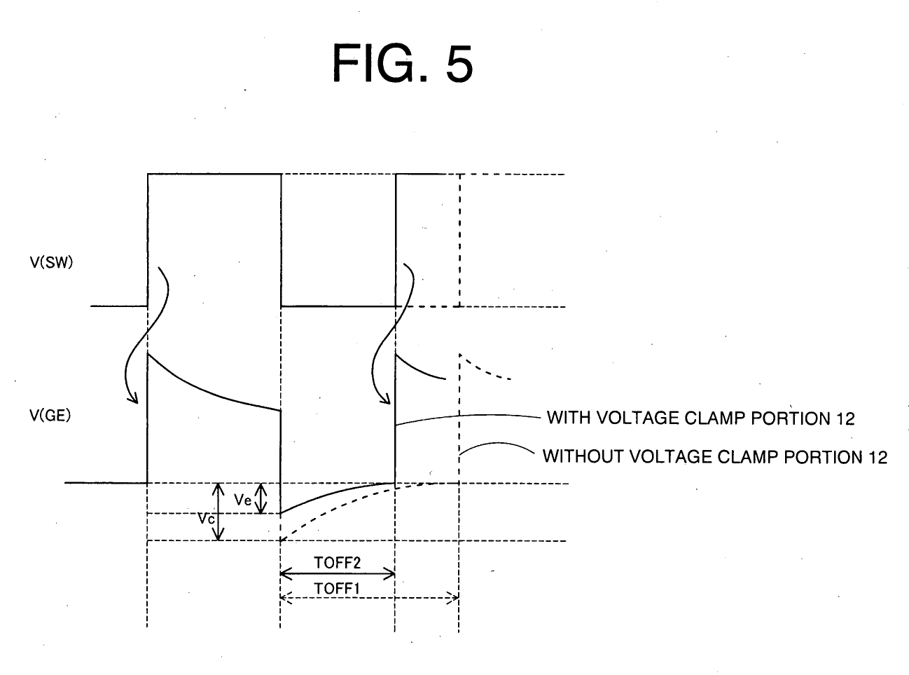

The above state is shown in FIG. 5. When there is not the voltage clamp portion 12 in the drive circuit (in the case of the first preferred embodiment), the initial gate voltage V (GE) upon the non-conduction is at the negative voltage value −Vc. When the there is the voltage clamp portion 12 in the drive circuit (in the case of the second preferred embodiment), the initial gate voltage V (GE) upon the non-conduction is clamped to the negative voltage value −Ve (Ve<Vc).

Since the gate voltage V (GE) is clamped to the smaller negative voltage value, the gate voltage V (GE) reaches 0V during a non-conduction period TOFF2 that is shorter than the non-conduction period TOFF1. Namely, the operation is shifted to the subsequent conduction period after the short non-conduction period TOFF2, and the IGBT device Q1 is quickly operated at a short cycle.

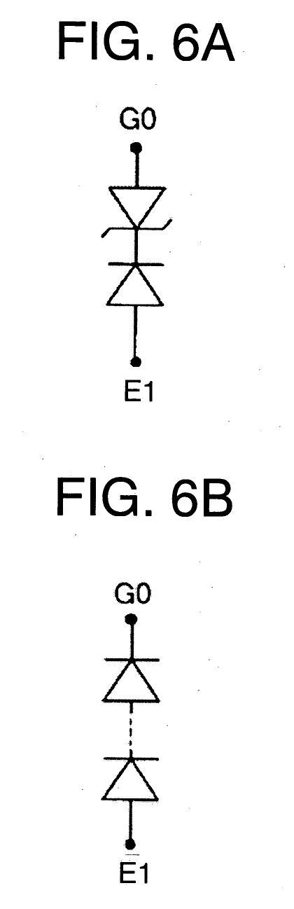

Third and fourth preferred embodiments that are modified from the second preferred embodiment are respectively shown in FIGS. 6A and 6B. The anode terminal of the diode device D1 is connected to that of the Zener diode ZD1 as shown in FIG. 4. However, as shown in FIG. 6A, the cathode terminal of the diode device D1 is connected to that of the Zener diode ZD1, and the anode terminals of the diode device D1 and the Zener diode ZD1 are respectively connected to the emitter terminal E1 and the terminal G0. Alternatively, a pair of diode devices is serially connected to each other as shown in FIG. 6B. In this case, the conduction is blocked in a reverse bias direction of the diode devices while a sum of the substantially constant forward voltages of the diodes is outputted as a clamp voltage in a forward bias direction of the diode devices.

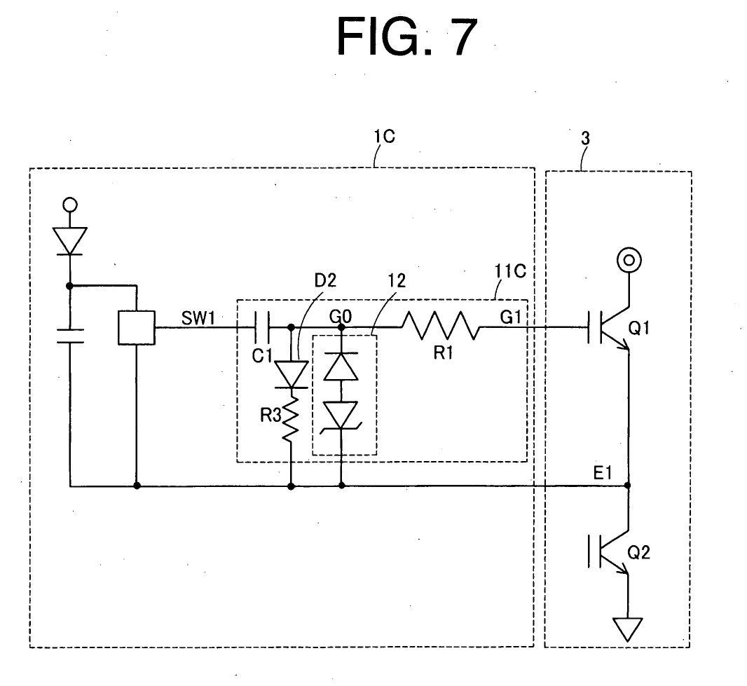

As shown in FIG. 7, a drive circuit according to a fifth preferred embodiment includes a level converting part 11C instead of the level converting part 11B according to the second preferred embodiment as shown in FIG. 4. The level converting part 11C includes a diode device D2 and a resistance device R3, instead of the resistance device R2 in the level converting part 11B. The diode device D2 is placed such that the forward bias direction of the diode device D2 is from the terminal G0 to the emitter terminal E1. A leakage route includes the diode device D2 and the resistance device R3. For example, when a power control board including the drive circuit 1C is different from a board on which the bridge driver 3 having the IGBT devices Q1 and Q2 is fitted, the leakage route is provided as a pseudo load upon circuit operation test only by the power control board.

When the switching control signal V (SW) transits from the low voltage level to the high voltage level upon the conduction of the IGBT device Q1 and the positive voltage is induced at the terminal G0, leak current flows via the diode device D2 and the resistance device R3, and the gate voltage V (GE) is steadily reduced before shifting the IGBT device Q1 to the non-conduction state. Thereby, the gate voltage V (GE) is at the negative voltage value due to the voltage transition of the switching control signal V (SW). A leakage route is not formed with respect to the gate voltage V (GE) of which the negative voltage value is induced, thus, the gate voltage V (GE) is steadily maintained at the negative voltage value over the non-conduction period.

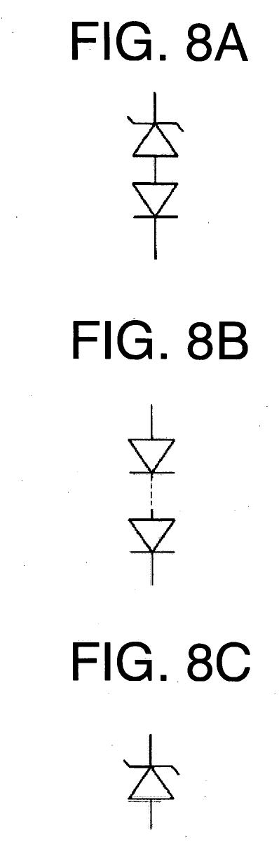

FIGS. 8A through 8C respectively show the structures of the voltage clamp portions in the drive circuit according to sixth through eighth preferred embodiments when the gate voltage V (GE) is clamped to the positive voltage value upon the conduction of the IGBT device Q1.

Concrete circuit structures of the voltage clamp portion are shown in FIGS. 8A thorough 8C. The circuit structures of the voltage clamp portions as shown in FIGS. 8A and 8B are respectively the same circuit structures as in the second preferred embodiment as shown in FIG. 4 and as in the fourth preferred embodiment as shown in FIG. 6B. Since the direction of voltage to be clamped is opposite from that in the second preferred embodiment, connecting direction to the terminal G0 and the emitter terminal E1 is reversed. However, the other circuit structure is the same. The circuit structure as shown in FIG. 8C only includes a Zener diode device. The positive gate voltage V (GE) is clamped by Zener voltage, and the negative gate voltage V (GE) is clamped by a forward bias voltage of the Zener diode device.

According to the drive circuits in the second through eighth preferred embodiments as described in detail above, a peak voltage value of the gate voltage V (GE) that is propagated by the capacitive coupling in response to the voltage transition of the switching control signal V (SW) is clamped to a predetermined voltage value by utilizing the voltage clamp portion. Thereby, a voltage reduction time of the gate voltage V (GE) is adjusted without adjusting the amount of leak voltage by varying the resistance values of the resistance devices R1 through R3. Also, the switching cycle is adjusted and shortened.

There is the case that a resistance device is provided between the gate terminal G1 and the emitter terminal E1 for preventing the unintentional ignition of the IGBT device Q1 at the stationary state. In this case, it is presumable that the resistance device also serves as the resistance device 2 for the leakage route. When the resistance value of the resistance device R2 cannot be changed in order to maintain the characteristics for preventing the unintentional ignition of the IGBT device Q1, the switching cycle is flexibly adjusted by clamping the peak voltage value of the gate voltage V (GE) to the predetermined voltage value.

According to the voltage clamp portion including the diode device and the Zener diode device, the gate voltage V (GE) is clamped to a sum of the Zener voltage as a predetermined voltage and the forward voltage of the diode, only in the forward bias direction of the diode device. The peak voltage value of the gate voltage V (GE) is selectively clamped upon either the conduction or the non-conduction of the IGBT device Q1. In addition, when the voltage clamp portion includes the diode device and the Zener diode device that are reversely connected to each other, the peak voltage value of the gate voltage V (GE) is clamped upon both the conduction and the non-conduction of the switching device.

When the voltage clamp portion includes the Zener diode, the peak voltage value of the gate voltage V (GE) is clamped upon both the conduction and the non-conduction of the IGBT device Q1.

According to the voltage clamp portion including a pair of the diode devices that are serially connected to one another, the gate voltage V (GE) is clamped to a sum of forward voltages as a predetermined voltage only in the forward bias direction of the diode devices. Also, the peak voltage value of the gate voltage V (GE) is selectively clamped upon either the conduction or the non-conduction of the IGBT device Q1. Also, when the voltage clamp portion includes a pair of the diodes that are reversely connected to each other, the peak voltage value of the gate voltage V (GE) is clamped upon both the conduction and the non-conduction of the IGBT device Q1.

The present invention is not limited to the above-described preferred embodiments, and various modifications are practiced according to the present invention.

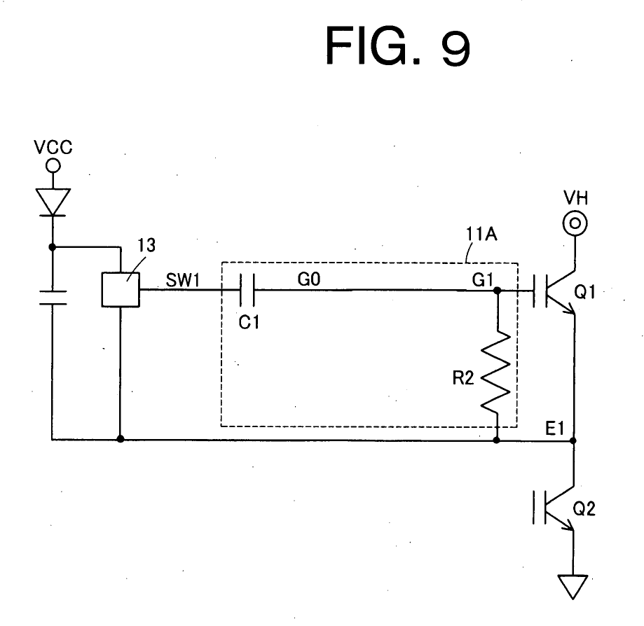

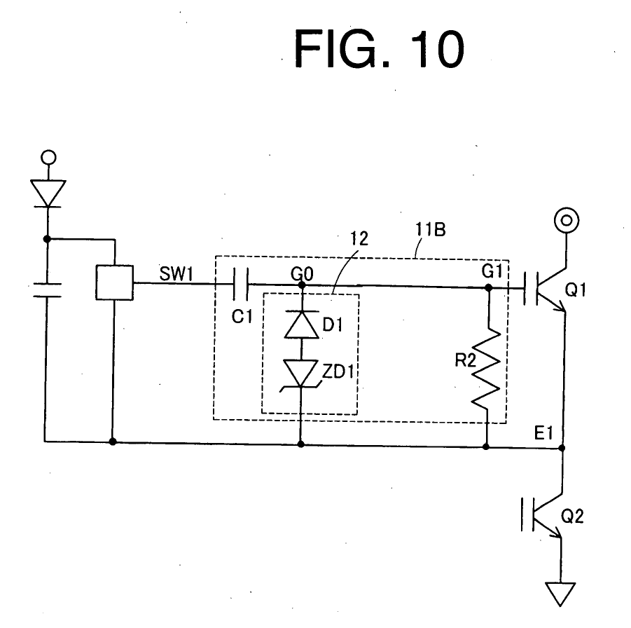

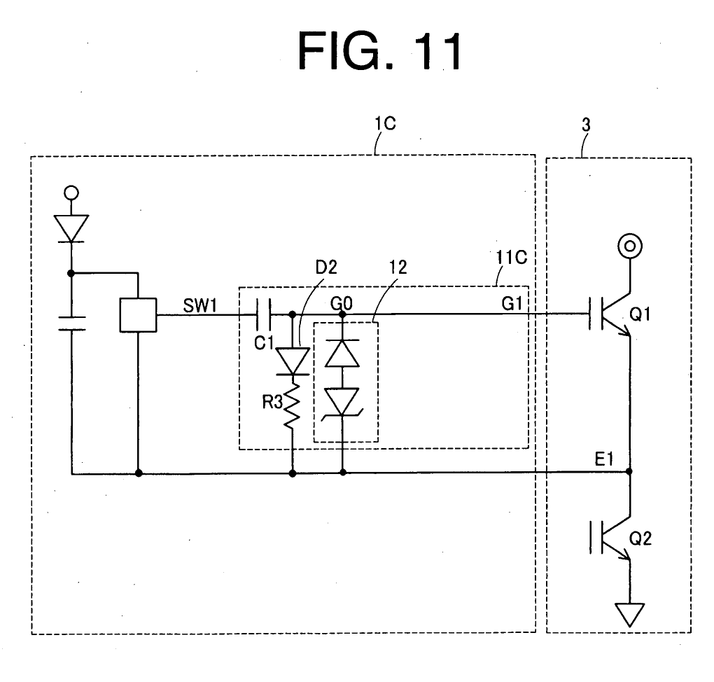

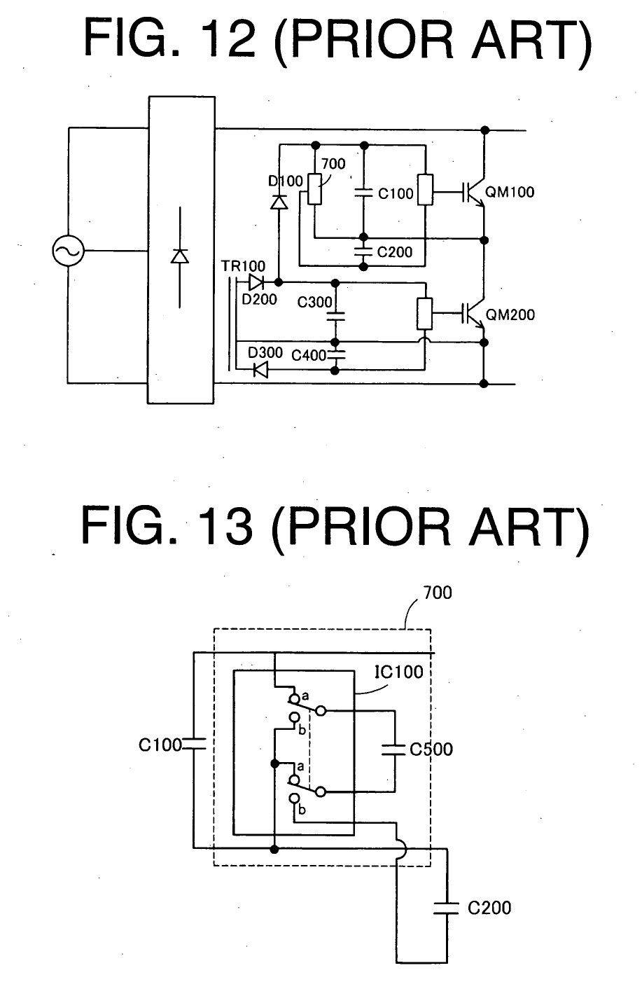

The terminal G0 of the condenser C1 is connected to the gate terminal G1 of the IGBT device G1 via the resistance device R1 as the current limiting device in the above-described preferred embodiments. However, the resistance device R1 is removed, and the terminal G0 of the condenser C1 is directly connected to the gate terminal G1 of the IGBT device G1 as shown in FIGS. 9 through 11. FIGS. 9 through 11 respectively show first through third alternative embodiments that are modified from the first, second and fifth preferred embodiments as shown in FIGS. 2, 4 and 7.

The IGBT device is utilized as the switching device in the above-preferred embodiments. However, if a MOS transistor or other voltage control device includes a control terminal that is controlled by voltage, the MOS transistor device or the other type voltage control device alternatively may be utilized as the switching device.

Also, in the above-described preferred embodiments, it is assumed that the small amount of the current flows in the resistance devices R1 and R2 at the stationary state, that the potential difference between the terminals of the resistance device R1 or R2 is small, and that the voltages of the terminal G0 and the gate terminal G1 are substantially the same. However, if the resistance values of the resistance devices R1 and R2 are appropriately chosen, the voltage applied to the terminal G0 is divided and is applied to the gate terminal G1.

Also, the wave form chart in the first preferred embodiment as shown in FIG. 3 shows the case that the gate voltage V (GE) is at 0V, that is, the gate terminal G1 and the emitter terminal E1 returns to the same electrical potential at the end of the non-conduction period TOFF1. However, for example, the CR time constant of the CR time constant circuit that includes the capacity elements due to the switching device such as the IGBT device Q1 and the other parasitic devices, and the leakage route such as the resistance devices R1 and R2 is set to be relatively large in comparison to the switching cycle. Thereby, the switching device is shifted from the non-conduction period to the conduction period when the anti-polarity applied voltage remains in the control terminal. Thus, regardless the fluctuation of the switching frequency, the substantially constant anti-polarity voltage is applied to the control terminal before shifting to the conduction period. The substantially constant voltage that is required for the conduction of the switching device is applied to the control terminal after shifting to the conduction period.

Therefore, the present examples and embodiments are to be considered as illustrative and not restrictive, and the invention is not to be limited to the details given herein but may be modified within the scope of the appended claims.

What is claimed is:

1. A drive circuit for a switching device including a standard terminal and a control terminal, conduction of the switching device being controlled in response to voltage that is applied to the control terminal with respect to the standard terminal, comprising:
a condenser having a first end and a second end, a switching control signal being inputted to the first end, the second end being connected to the control terminal; and
a leakage route connecting the standard terminal and the control terminal.

2. The drive circuit according to claim 1, further comprising a current limiting device connected between the second end and the control terminal.

3. The drive circuit according to claim 2, wherein the leakage route includes a resistance device.

4. The drive circuit according to claim 2, wherein the leakage route includes a resistance device and a diode device.

5. The drive circuit according to claim 2, further comprising a voltage clamp portion connected between the standard terminal and the control terminal for clamping the voltage to a predetermined voltage value when the switching device is in at least one of a conduction state and a non-conduction state.

6. The drive circuit according to claim 5, wherein the voltage clamp portion includes a diode device that has a cathode terminal and an anode terminal and a Zener diode device that has a cathode terminal and an anode terminal, the anode terminals of the diode device and the Zener diode device being connected to one another, the cathode terminal of the diode device being connected to the control terminal, the cathode of the Zener diode device being connected to the standard terminal.

7. The drive circuit according to claim 5, wherein the voltage clamp portion includes a diode device that has a cathode terminal and an anode terminal and a Zener diode device that has a cathode terminal and an anode terminal, the cathode terminals of the diode device and the Zener diode device being connected to one another, the anode terminals of the diode device being connected to the standard terminal, the anode of the Zener diode device being connected to the control terminal.

8. The drive circuit according to claim 5, wherein the voltage clamp portion includes a diode device that has a cathode terminal and an anode terminal and a Zener diode device that has a cathode terminal and an anode terminal, the anode terminals of the diode device and the Zener diode device being connected to one another, the cathode terminal of the diode device being connected to the standard terminal, the cathode of the Zener diode device being connected to the control terminal.

9. The drive circuit according to claim 5, wherein the voltage clamp portion includes a Zener diode device.

10. The drive circuit according to claim 5, wherein the voltage clamp portion includes a predetermined number of diode devices that are serially connected to each other.

11. The drive circuit according to claim 1, wherein the second end of the condenser is directly connected to the control terminal.

12. The drive circuit according to claim 11, wherein the leakage route includes a resistance device.

13. The drive circuit according to claim 11, wherein the leakage route includes a resistance device and a diode device.

14. The drive circuit according to claim 11, further comprising a voltage clamp portion connected between the standard terminal and the control terminal for clamping the voltage to a predetermined voltage value when the switching device is in at least one of a conduction state and a non-conduction state.

15. The drive circuit according to claim 14, wherein the voltage clamp portion includes a diode device that has a cathode terminal and an anode terminal and a Zener diode device that has a cathode terminal and an anode terminal, the anode terminals of the diode device and the Zener diode device being connected to one another, the cathode terminal of the diode device being connected to the control terminal, the cathode of the Zener diode device being connected to the standard terminal.

16. A drive method for a switching device including a standard terminal and a control terminal, conduction of the switching device being controlled in response to voltage that is applied to the control terminal with respect to the standard terminal, the drive method comprising the steps of:
propagating transition of voltage level of a switching control signal to the control terminal by capacitive coupling so as to set an initial value of the voltage; and
reducing the voltage after the propagating step.

17. The drive method according to claim 16, wherein the propagating step includes clamping the voltage to a predetermined voltage value when the switching device is in at least one of a conduction state and a non-conduction state.
